(19) United States
(12) Patent Application Publication
(10) Pub. No.: US 2024/0234131 A1
(43) Pub. Date: Jul. 11, 2024

(54) DIRECTIONAL SELECTIVE FILL USING HIGH DENSITY PLASMA

(71) Applicant: Applied Materials, Inc., Santa Clara, CA (US)

(72) Inventors: Purvam Dineshbhai Modi, Sunnyvale, CA (US); Bhargav S. Citla, Fremont, CA (US); Srinivas D. Nemani, Saratoga, CA (US); Ellie Y. Yieh, San Jose, CA (US)

(73) Assignee: Applied Materials, Inc., Santa Clara, CA (US)

(21) Appl. No.: 18/584,540

(22) Filed: Feb. 22, 2024

Related U.S. Application Data
(63) Continuation-in-part of application No. 18/229,285, filed on Aug. 2, 2023.
Application No. 18/229,285 is a continuation of application No. 17/469,529, filed on Sep. 8, 2021, now Pat. No. 11,862,458.

(51) Int. Cl. H01L 21/02; H01J 37/32; H01L 21/3065; H01L 21/311

(52) U.S. Cl. CPC H01L 21/02274; H01J 37/32146; H01L 21/3065; H01L 21/31116; H01J 2237/332; H01J 2237/334

(57) ABSTRACT

Exemplary processing methods may include providing a silicon-containing precursor to a processing region of a semiconductor processing chamber. A substrate may be housed in the processing region. The substrate may define a feature. The methods may include forming plasma effluents of the silicon-containing precursor. The methods may include depositing a silicon-containing material on the substrate. The methods may include providing an oxygen-containing precursor to the processing region, forming plasma effluents of the oxygen-containing precursor, and contacting the silicon-containing material with the plasma effluents of the oxygen-containing precursor to form a silicon-and-oxygen-containing material. The methods may include providing a fluorine-containing precursor to the processing region, forming plasma effluents of the fluorine-containing precursor, and etching the silicon-and-oxygen-containing material from a top, a sidewall, or both of the feature with the plasma effluents of the fluorine-containing precursor.

### CROSS-REFERENCE TO RELATED APPLICATIONS

This application is a continuation-in-part of U.S. application Ser. No. 18/229,285, filed Aug. 2, 2023, which is a continuation of U.S. application Ser. No. 17/469,529, filed Sep. 8, 2021, are hereby incorporated by reference in their entirety for all purposes.

### TECHNICAL FIELD

The present technology relates to semiconductor processing. More specifically, the present technology relates to methods of depositing, etching, and converting materials including silicon-containing films using high density plasma.

### BACKGROUND

Integrated circuits are made possible by processes which produce intricately patterned material layers on substrate surfaces. Producing patterned material on a substrate requires controlled methods of formation and removal of exposed material. As device sizes continue to shrink, material formation may affect subsequent operations. For example, in gap filling operations a material may be formed or deposited to fill a trench or other feature formed on a semiconductor substrate. As features may be characterized by higher aspect ratios and reduced critical dimensions, these filling operations may be challenged. For example, as the deposition may occur at the top and along sidewalls of the feature, continued deposition may pinch off the feature including between sidewalls within the feature, and may produce voids within the feature. This can impact device performance and subsequent processing operations.

Thus, there is a need for improved systems and methods that can be used to produce high quality devices and structures. These and other needs are addressed by the present technology.

### SUMMARY

Exemplary processing methods may include providing a silicon-containing precursor to a processing region of a semiconductor processing chamber. A substrate may be housed in the processing region. The substrate may define a feature. The methods may include forming plasma effluents of the silicon-containing precursor. The methods may include depositing a silicon-containing material on the substrate. The methods may include providing an oxygen-containing precursor to the processing region, forming plasma effluents of the oxygen-containing precursor, and contacting the silicon-containing material with the plasma effluents of the oxygen-containing precursor to form a silicon-and-oxygen-containing material. The methods may include providing a fluorine-containing precursor to the processing region, forming plasma effluents of the fluorine-containing precursor, and etching the silicon-and-oxygen-containing material from a top, a sidewall, or both of the feature with the plasma effluents of the fluorine-containing precursor.

In some embodiments, the feature may be characterized by an aspect ratio of greater than or about 1:1. The feature may be characterized by a width across the feature of less than or about 100 nm. The oxygen-containing precursor may be or include diatomic oxygen (O₂), nitrous oxide (N₂O), or hydrogen peroxide (H₂O₂). The methods may include applying a bias power from a bias power source to the substrate support. A plasma power source may be operated in a continuous wave mode while the bias power source may be operated in a pulsing mode during the depositing and the etching. The plasma effluents of the silicon-containing precursor may be formed at a first power level from a plasma power source. The plasma effluents of the fluorine-containing precursor may be formed at a second power level from the plasma power source greater than the first power level. The fluorine-containing precursor may be or include diatomic fluorine (F₂), nitrogen trifluoride (NF₃), ammonia (NH₃), octafluorocyclobutane (C₄F₈), carbon tetrafluoride (CF₄), or hexafluorobutadiene (C₄F₆). The etching may remove silicon-and-oxygen-containing material at a rate of less than or about 10 Å/second. The method may be repeated for a second cycle. A temperature of the substrate may be maintained at a temperature of less than or about 450° C. A pressure within the semiconductor processing chamber may be maintained at a pressure of less than or about 10 Torr.

Some embodiment of the present technology may encompass semiconductor processing methods. The methods may include i) forming plasma effluents of a silicon-containing precursor. The methods may include ii) depositing a silicon-containing material on a substrate. The substrate may define a feature. The substrate may be seated on a substrate support. The methods may include iii) forming plasma effluents of an oxygen-containing precursor. The methods may include iv) contacting the silicon-containing material with the plasma effluents of the oxygen-containing precursor to form a silicon-and-oxygen-containing material. The methods may include v) forming plasma effluents of a fluorine-containing precursor. The methods may include vi) contacting the silicon-and-oxygen-containing material with plasma effluents of the fluorine-containing precursor. The contacting may etch the silicon-and-oxygen-containing material from a sidewall of the feature. The methods may include repeating operations i) through vi) to iteratively fill the feature.

In some embodiments, a plasma power during operation iii) may be maintained at greater than or about 600 W. A plasma power may be pulsed during operations i) through iv). The etching may fully remove the silicon-and-oxygen-containing material from sidewalls of the feature above a base fill of the feature. The methods may include applying a bias power from a bias power source during the semiconductor processing method. The bias power source may be operated at a plasma power of less than or about 750 W. A temperature of the substrate may be maintained at a temperature of less than or about 450° C.

Some embodiment of the present technology may encompass semiconductor processing methods. The methods may include providing a silicon-containing precursor to a processing region of a semiconductor processing chamber. A substrate may be housed in the processing region. The substrate may define a feature. The processing region may be at least partially defined between a faceplate and a substrate support on which the substrate is seated. The methods may include forming plasma effluents of the silicon-containing precursor. The plasma effluents of the silicon-containing precursor may be formed at a first power level from a plasma power source. The methods may include depositing a silicon-containing material on the substrate. The methods may include providing an oxygen-containing precursor to the processing region of the semiconductor processing chamber. The methods may include forming plasma effluents of the oxygen-containing precursor. The methods may include contacting the silicon-containing material with the plasma effluents of the oxygen-containing precursor to oxidize the silicon-containing material. The contacting may form a silicon-and-oxygen-containing material. The methods may include providing a fluorine-containing precursor to the processing region of the semiconductor processing chamber. The methods may include forming plasma effluents of the fluorine-containing precursor. The plasma effluents of the fluorine-containing precursor may be formed at a second power level from the plasma power source greater than the first power level. The methods may include contacting the silicon-and-oxygen-containing material with plasma effluents of the fluorine-containing precursor. The contacting may etch the silicon-and-oxygen-containing material from sidewalls of the feature above a base fill of the feature.

In some embodiments, a temperature of the substrate may be maintained at a temperature of less than or about 450° C.

Such technology may provide numerous benefits over conventional systems and techniques. For example, by performing a high density deposition, a quality of material produced within features from the bottom may improve, which may differentiate the quality from material on the sidewalls. Additionally, by performing an etch operation according to embodiments of the present technology, sidewall coverage can be etched selectively relative to the higher quality, treated material. These and other embodiments, along with many of their advantages and features, are described in more detail in conjunction with the below description and attached figures.

### BRIEF DESCRIPTION OF THE DRAWINGS

A further understanding of the nature and advantages of the disclosed technology may be realized by reference to the remaining portions of the specification and the drawings.

FIG. 1 shows a schematic cross-sectional view of an exemplary processing chamber according to some embodiments of the present technology.

FIG. 2 shows exemplary operations in a processing method according to some embodiments of the present technology.

FIGS. 3A-3C show schematic cross-sectional views of a substrate during a processing according to some embodiments of the present technology.

Several of the figures are included as schematics. It is to be understood that the figures are for illustrative purposes and are not to be considered of scale unless specifically stated to be of scale. Additionally, as schematics, the figures are provided to aid comprehension and may not include all aspects or information compared to realistic representations and may include exaggerated material for illustrative purposes.

In the appended figures, similar components and/or features may have the same reference label. Further, various components of the same type may be distinguished by following the reference label by a letter that distinguishes among the similar components. If only the first reference label is used in the specification, the description is applicable to any one of the similar components having the same first reference label irrespective of the letter.

### DETAILED DESCRIPTION

Silicon-and-oxygen-containing material may be used in semiconductor device manufacturing for a number of structures and processes. Some examples include using silicon-and-oxygen-containing material as a sacrificial material. For example, the silicon-and-oxygen-containing material may be used as, but is not limited to, a dummy gate material or as a trench fill material. In gap filling operations, some processing may utilize plasma-enhanced deposition under process conditions to increase the directionality of the deposition, which may allow the deposited material to better fill features on the substrate.

As feature sizes continue to shrink, plasma-enhanced depositions may be challenged for narrow features, which may be further characterized by higher aspect ratios. For example, pinching-off in the feature may more readily occur due to deposition on sidewalls of the feature, which in small feature sizes may further restrict flow and deposition into the feature, and may produce seams or voids in the feature. Conventional technologies have attempted to address the formation of seams or voids by utilizing flowable materials to fill trenches or features. However, to convert the flowable materials to oxide materials, an operation such as a steam anneal may be necessary. In many applications, a steam anneal to cure the flowable materials may be well above thermal budgets. The present technology may overcome these limitations by depositing material through a cycle of deposition, conversion, and etching. The deposition may selectively deposit silicon-containing material, such as amorphous silicon, towards a bottom portion of the trench or feature through the application of a high density plasma. The conversion may incorporate oxygen into the material and form a silicon-and-oxygen-containing material. In order to prevent the clogging or pinching-off of the feature, which could form a void or seam, an etch may remove material from the sidewalls and or upper portion of the features. By repeating these cycles, a feature may be filled with silicon-and-oxygen-containing material without the formation of a void or seam.

After describing general aspects of a chamber according to some embodiments of the present technology in which plasma processing operations discussed below may be performed, specific methodology may be discussed. It is to be understood that the present technology is not intended to be limited to the specific films, chambers or processes discussed, as the techniques described may be used to improve a number of film formation processes, and may be applicable to a variety of processing chambers and operations.

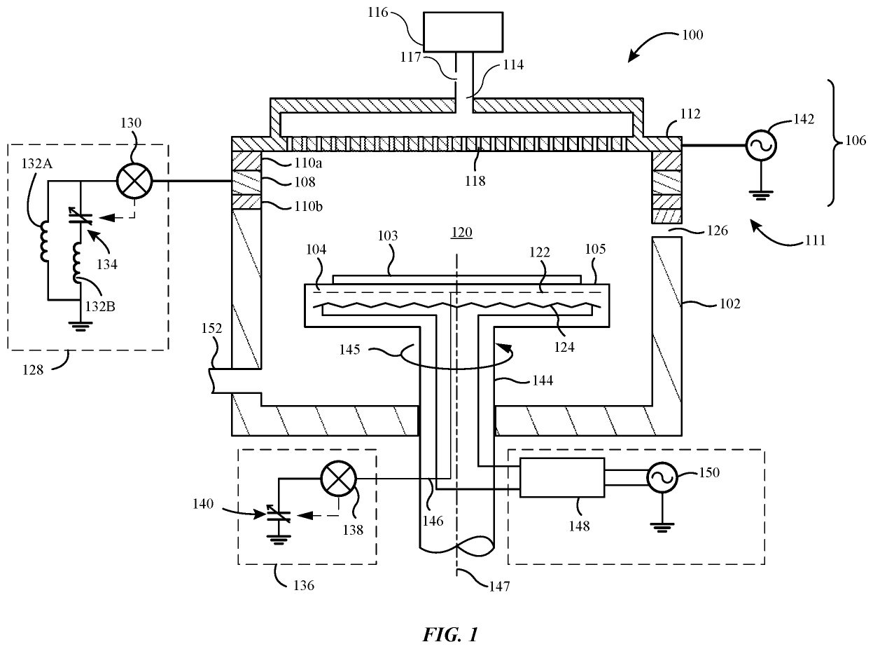

FIG. 1 shows a cross-sectional view of an exemplary processing chamber 100 according to some embodiments of the present technology. The figure may illustrate an overview of a system incorporating one or more aspects of the present technology, and/or which may perform one or more deposition or other processing operations according to embodiments of the present technology. Additional details of chamber 100 or methods performed may be described further below. Chamber 100 may be utilized to form film layers according to some embodiments of the present technology, although it is to be understood that the methods may similarly be performed in any chamber within which film formation may occur. The processing chamber 100 may include a chamber body 102, a substrate support 104 disposed inside the chamber body 102, and a lid assembly 106 coupled with the chamber body 102 and enclosing the substrate support 104 in a processing volume 120. A substrate 103 may be provided to the processing volume 120 through an opening 126, which may be conventionally sealed for processing using a slit valve or door. The substrate 103 may be seated on a surface 105 of the substrate support during processing. The substrate support 104 may be rotatable, as indicated by the arrow 145, along an axis 147, where a shaft 144 of the substrate support 104 may be located. Alternatively, the substrate support 104 may be lifted to rotate as necessary during a deposition process.

A plasma profile modulator 111 may be disposed in the processing chamber 100 to control plasma distribution across the substrate 103 disposed on the substrate support 104. The plasma profile modulator 111 may include a first electrode 108 that may be disposed adjacent to the chamber body 102, and may separate the chamber body 102 from other components of the lid assembly 106. The first electrode 108 may be part of the lid assembly 106, or may be a separate sidewall electrode. The first electrode 108 may be an annular electrode. The first electrode 108 may be a continuous loop around a circumference of the processing chamber 100 surrounding the processing volume 120, or may be discontinuous at selected locations if desired. The first electrode 108 may also be a perforated electrode, such as a perforated ring or a mesh electrode, or may be a plate electrode, such as, for example, a secondary gas distributor.

One or more isolators 110a, 110b, which may be a dielectric material such as a ceramic or metal oxide, for example aluminum oxide and/or aluminum nitride, may contact the first electrode 108 and separate the first electrode 108 electrically and thermally from a gas distributor 112, also referred to as a faceplate, and from the chamber body 102. The gas distributor 112 may define apertures 118 for distributing process precursors into the processing volume 120. The gas distributor 112 may be coupled with a first source of electric power 142, such as an RF generator, RF power source, DC power source, pulsed DC power source, pulsed RF power source, or any other power source that may be coupled with the processing chamber. In some embodiments, the first source of electric power 142 may be an RF power source.

The gas distributor 112 may be a conductive gas distributor or a non-conductive gas distributor. The gas distributor 112 may also be formed of conductive and non-conductive components. For example, a body of the gas distributor 112 may be conductive while a face plate of the gas distributor 112 may be non-conductive. The gas distributor 112 may be powered, such as by the first source of electric power 142 as shown in FIG. 1, or the gas distributor 112 may be coupled with ground in some embodiments.

The first electrode 108 may be coupled with a first tuning circuit 128 that may control a ground pathway of the processing chamber 100. The first tuning circuit 128 may include a first electronic sensor 130 and a first electronic controller 134. The first electronic controller 134 may be or include a variable capacitor or other circuit elements. The first tuning circuit 128 may be or include one or more inductors 132. The first tuning circuit 128 may be any circuit that enables variable or controllable impedance under the plasma conditions present in the processing volume 120 during processing. In some embodiments as illustrated, the first tuning circuit 128 may include a first circuit leg and a second circuit leg coupled in parallel between ground and the first electronic sensor 130. The first circuit leg may include a first inductor 132A. The second circuit leg may include a second inductor 132B coupled in series with the first electronic controller 134. The second inductor 132B may be disposed between the first electronic controller 134 and a node connecting both the first and second circuit legs to the first electronic sensor 130. The first electronic sensor 130 may be a voltage or current sensor and may be coupled with the first electronic controller 134, which may afford a degree of closed-loop control of plasma conditions inside the processing volume 120.

A second electrode 122 may be coupled with the substrate support 104. The second electrode 122 may be embedded within the substrate support 104 or coupled with a surface of the substrate support 104. The second electrode 122 may be a plate, a perforated plate, a mesh, a wire screen, or any other distributed arrangement of conductive elements. The second electrode 122 may be a tuning electrode, and may be coupled with a second tuning circuit 136 by a conduit 146, for example a cable having a selected resistance, such as 50 ohms, for example, disposed in the shaft 144 of the substrate support 104. The second tuning circuit 136 may have a second electronic sensor 138 and a second electronic controller 140, which may be a second variable capacitor. The second electronic sensor 138 may be a voltage or current sensor, and may be coupled with the second electronic controller 140 to provide further control over plasma conditions in the processing volume 120.

A third electrode 124, which may be a bias electrode and/or an electrostatic chucking electrode, may be coupled with the substrate support 104. The third electrode may be coupled with a second source of electric power 150 through a filter 148, which may be an impedance matching circuit. The second source of electric power 150 may be DC power, pulsed DC power, RF bias power, a pulsed RF source or bias power, or a combination of these or other power sources. In some embodiments, the second source of electric power 150 may be an RF bias power.

The lid assembly 106 and substrate support 104 of FIG. 1 may be used with any processing chamber for plasma or thermal processing. In operation, the processing chamber 100 may afford real-time control of plasma conditions in the processing volume 120. The substrate 103 may be disposed on the substrate support 104, and process gases may be flowed through the lid assembly 106 using an inlet 114 according to any desired flow plan. Gases may exit the processing chamber 100 through an outlet 152. Electric power may be coupled with the gas distributor 112 to establish a plasma in the processing volume 120. The substrate may be subjected to an electrical bias using the third electrode 124 in some embodiments.

Upon energizing a plasma in the processing volume 120, a potential difference may be established between the plasma and the first electrode 108. A potential difference may also be established between the plasma and the second electrode 122. The electronic controllers 134, 140 may then be used to adjust the flow properties of the ground paths represented by the two tuning circuits 128 and 136. A set point may be delivered to the first tuning circuit 128 and the second tuning circuit 136 to provide independent control of deposition rate and of plasma density uniformity from center to edge. In embodiments where the electronic controllers may both be variable capacitors, the electronic sensors may adjust the variable capacitors to maximize deposition rate and minimize thickness non-uniformity independently.

Each of the tuning circuits 128, 136 may have a variable impedance that may be adjusted using the respective electronic controllers 134, 140. Where the electronic controllers 134, 140 are variable capacitors, the capacitance range of each of the variable capacitors, and the inductances of the first inductor 132A and the second inductor 132B, may be chosen to provide an impedance range. This range may depend on the frequency and voltage characteristics of the plasma, which may have a minimum in the capacitance range of each variable capacitor. Hence, when the capacitance of the first electronic controller 134 is at a minimum or maximum, impedance of the first tuning circuit 128 may be high, resulting in a plasma shape that has a minimum aerial or lateral coverage over the substrate support. When the capacitance of the first electronic controller 134 approaches a value that minimizes the impedance of the first tuning circuit 128, the aerial coverage of the plasma may grow to a maximum, effectively covering the entire working area of the substrate support 104. As the capacitance of the first electronic controller 134 deviates from the minimum impedance setting, the plasma shape may shrink from the chamber walls and aerial coverage of the substrate support may decline. The second electronic controller 140 may have a similar effect, increasing and decreasing aerial coverage of the plasma over the substrate support as the capacitance of the second electronic controller 140 may be changed.

The electronic sensors 130, 138 may be used to tune the respective circuits 128, 136 in a closed loop. A set point for current or voltage, depending on the type of sensor used, may be installed in each sensor, and the sensor may be provided with control software that determines an adjustment to each respective electronic controller 134, 140 to minimize deviation from the set point. Consequently, a plasma shape may be selected and dynamically controlled during processing. It is to be understood that, while the foregoing discussion is based on electronic controllers 134, 140, which may be variable capacitors, any electronic component with adjustable characteristic may be used to provide tuning circuits 128 and 136 with adjustable impedance.

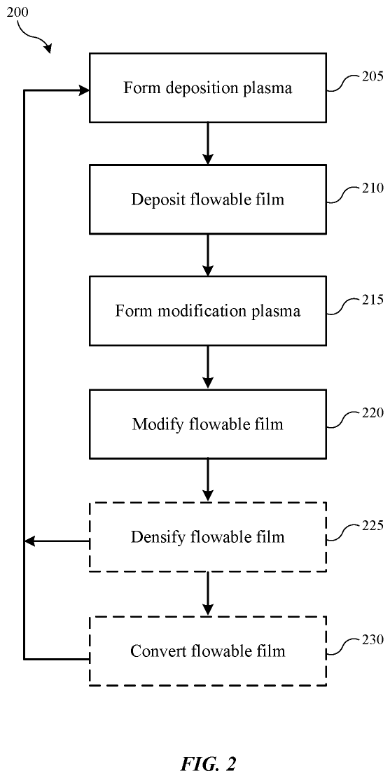

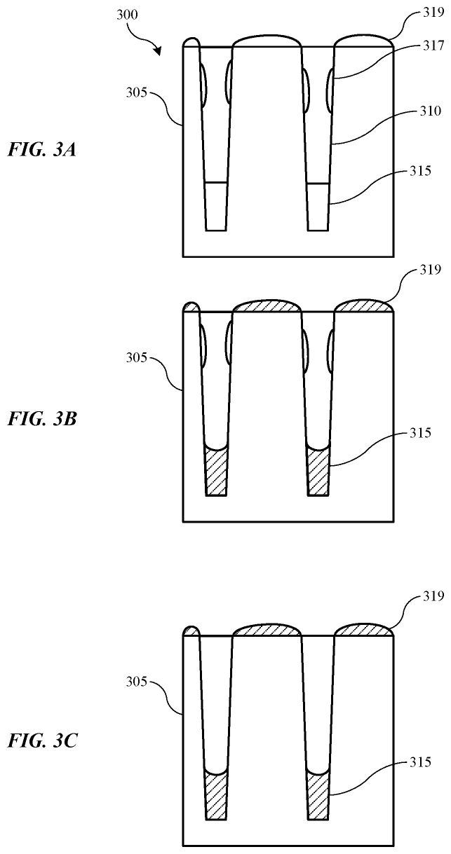

Processing chamber 100 may be utilized in some embodiments of the present technology for processing methods that may include formation or etching of materials for semiconductor structures. It is to be understood that the chamber described is not to be considered limiting, and any chamber that may be configured to perform operations as described may be similarly used. FIG. 2 shows exemplary operations in a processing method 200 according to some embodiments of the present technology. The method may be performed in a variety of processing chambers and on one or more mainframes or tools, including processing chamber 100 described above. Method 200 may include a number of optional operations, which may or may not be specifically associated with some embodiments of methods according to the present technology. For example, many of the operations are described in order to provide a broader scope of the structural formation, but are not critical to the technology, or may be performed by alternative methodology as would be readily appreciated. Method 200 may describe operations shown schematically in FIGS. 3A-3C, the illustrations of which will be described in conjunction with the operations of method 200. It is to be understood that the figures illustrate only partial schematic views, and a substrate may contain any number of additional materials and features having a variety of characteristics and aspects as illustrated in the figures.

Method 200 may include additional operations prior to initiation of the listed operations. For example, additional processing operations may include forming structures on a substrate, which may include both forming and removing material. For example, transistor structures, memory structures, or any other structures may be formed. Prior processing operations may be performed in the chamber in which method 200 may be performed, or processing may be performed in one or more other processing chambers prior to delivering the substrate into the semiconductor processing chamber or chambers in which method 200 may be performed. Regardless, method 200 may optionally include delivering a semiconductor substrate to a processing region of a semiconductor processing chamber, such as processing chamber 100 described above, or other chambers that may include components as described above. The substrate may be deposited on a substrate support, which may be a pedestal such as substrate support 104, and which may reside in a processing region of the chamber, such as processing volume 120 described above.

A substrate on which several operations have been performed may be substrate 305 of a structure 300, which may show a partial view of a substrate on which semiconductor processing may be performed. It is to be understood that structure 300 may show only a few top layers during processing to illustrate aspects of the present technology. The substrate 305 may include a material in which one or more features 310 may be formed. Substrate 305 may be any number of materials used in semiconductor processing. The substrate material may be or include silicon, germanium, dielectric materials including silicon oxide or silicon nitride, metal materials, or any number of combinations of these materials, which may be the substrate 305, or materials formed in structure 300. Features 310 may be characterized by any shape or configuration according to the present technology. In some embodiments, the features may be or include a trench structure or aperture formed within the substrate 305.

Although the features 310 may be characterized by any shapes or sizes, in some embodiments the features 310 may be characterized by higher aspect ratios, or a ratio of a depth of the feature to a width across the feature. For example, in some embodiments features 310 may be characterized by aspect ratios greater than or about 1:1, and may be characterized by aspect ratios greater than or about 2:1, greater than or about 3:1, greater than or about 5:1, greater than or about 10:1, greater than or about 15:1, or greater. Additionally, the features may be characterized by narrow widths or diameters across the feature including between two sidewalls, such as a dimension less than or about 100 nm, and may be characterized by a width across the feature of less than or about 90 nm, less than or about 80 nm, less than or about 70 nm, less than or about 60 nm, less than or about 50 nm, less than or about 40 nm, less than or about 30 nm, less than or about 20 nm, less than or about 17 nm, less than or about 15 nm, less than or about 12 nm, less than or about 10 nm, less than or about 9 nm, less than or about 8 nm, less than or about 7 nm, less than or about 6 nm, less than or about 5 nm, or less.

In some embodiments, method 200 may include optional treatment operations, such as a pretreatment, that may be performed to prepare a surface of substrate 305 for deposition. Once prepared, method 200 may include providing one or more deposition precursors to a processing region of the semiconductor processing chamber housing the structure 300 at operation 205. The deposition precursors may include one or more silicon-containing precursors, as well as one or more diluents or carrier gases such as an inert gas or other gas delivered with the silicon-containing precursor. Silicon-containing precursors that may be used during the deposition of silicon-containing material 315 may include, but are not limited to, silane (SiH₄), disilane (Si₂H₆), trisilane (Si₃H₈), tetrasilane (Si₄H₁₀), pentasilane (Si₅H₁₂), or other organosilanes including cyclohexasilanes, silicon tetrafluoride (SiF₄), silicon tetrachloride (SiCl₄), dichlorosilane (SiH₂Cl₂), tetraethyl orthosilicate (TEOS), as well as any other silicon-containing precursors that may be used in silicon-containing film formation.

In embodiments, a flow rate of the deposition precursors, such as the silicon-containing precursor, may be a lower flow rate. The high density plasma process of method 200 may result in increased deposition rates at conventional flow rates. Accordingly, to control deposition rates, the flow rate of the deposition precursors may be maintained at less than or about 50 sccm, and may be maintained at less than or about 40 sccm, less than or about 30 sccm, less than or about 20 sccm, less than or about 15 sccm, less than or about 10 sccm, less than or about 9 sccm, less than or about 8 sccm, less than or about 7 sccm, less than or about 6 sccm, less than or about 5 sccm, or less.

Deposition plasma effluents may be formed of the deposition precursors including the silicon-containing precursor at operation 210. The deposition plasma effluents may be formed within the processing region, which may allow deposition materials to deposit on the substrate. For example, in some embodiments an inductively-coupled plasma may be formed within the processing region by applying plasma power to the faceplate, chamber, or substrate support as previously described.

The power applied during deposition may be a high power plasma, which may increase dissociation, and which may provide a high density plasma. Accordingly, in some embodiments a plasma power source may deliver a plasma power to the faceplate, chamber, or substrate support of greater than or about 1,500 W, and may deliver a power of greater than or about 2,000 W, greater than or about 2,500 W, greater than or about 3,000 W, greater than or about 3,500 W, greater than or about 4,000 W, greater than or about 4,500 W, greater than or about 5,000 W, greater than or about 5,500 W, greater than or about 6,000 W, or more. At plasma powers less than, for example, 1,000 W, a high density plasma may not be formed, and the resultant reduced flux of the plasma may not force the plasma effluents into the features 310.

A silicon-containing material 315 may be deposited on the substrate at operation 215 from plasma effluents of the silicon-containing precursor. The silicon-containing material 315 may be or include amorphous silicon. The high power plasma and resultant high density plasma may provide a high quality silicon-containing material 315, such as high quality amorphous silicon. The deposited materials may at least partially fill the features on the substrate to provide a bottom-up type of gap fill. As illustrated in FIG. 3A, silicon-containing material 315 may be deposited on the substrate 305, and deposit at the bottom of the features 310, as well as above the features 310 on the substrate 305 and on the sidewalls of the features 310. Although the amount of silicon-containing material 315 deposited on the sidewalls may be relatively small or thin, continued formation may cause the features 310 to be pinched off. If pinched off, the formation of a seam or void in the material may occur as the gap fill continues. Accordingly, a series of depositions, conversions, and etches, as further described below, may be performed to deposit seam-free silicon-containing material, such as silicon-and-oxygen-containing material, in the features 310.

During or subsequent operation 215, an amount of densification of the silicon-containing material 315 may be performed. The densification may include bombarding the deposited silicon-containing material 315 with the one or more diluents or carrier gases such as an inert gas or other gas delivered with the silicon-containing precursor. While silicon-containing material 315 deposited at upper portions, such as the top of the features 310, may also be densified, silicon-containing material 315 deposited on the sidewalls of the features 310 may not be densified. Accordingly, the densification may selectively treat silicon-containing material 315 perpendicular to the direction of the diluent or carrier gas being directed to the substrate 305.

In some embodiments of the present technology a conversion operation may be performed that is configured to convert the silicon-containing material 315 to a silicon-and-oxygen-containing material. This operation may be performed in the same chamber as the deposition. In some embodiments, the silicon-containing precursor flow may be halted and the processing region may be purged. Subsequent a purge, an oxygen-containing precursor may be provided to the processing region of the semiconductor processing chamber at operation 220. Although any oxygen-containing precursor may be used, in some embodiments diatomic oxygen (O₂), nitrous oxide (N₂O), hydrogen peroxide (H₂O₂), or other oxygen-containing materials useful in semiconductor processing may be used as the oxygen-containing precursor to produce the conversion plasma, along with one or more additional precursors. In embodiments, O₂ may provide a better profile during conversion and/or result in less sputtering. Without being bound to any particular theory, O₂ may provide a better profile during conversion and/or result in less sputtering compared to N₂O as N₂O is a heavier oxidation gas than O₂. Conversion plasma effluents may be formed at operation 225, which may also be an inductively-coupled plasma formed within the processing region, although in some embodiments a capacitively-coupled plasma may similarly be applied. The conversion plasma effluents may be formed by applying a plasma power to the faceplate, chamber, or substrate support, and in some embodiments no other power source may be engaged.

Compared to the power applied during deposition, the conversion plasma effluents may be formed at a lower plasma power from the plasma power source, which may oxidize the silicon-containing material 315. Accordingly, in embodiments, the plasma power source may deliver a plasma power to the faceplate, chamber, or substrate support of less than or about 2,500 W, and may deliver a power of less than or about 2,250 W, less than or about 2,000 W, less than or about 1,750 W, less than or about 1,700 W, less than or about 1,600 W, less than or about 1,500 W, less than or about 1,400 W, less than or about 1,300 W, less than or about 1,200 W, less than or about 1,100 W, less than or about, 1,000 W, or less. At plasma powers to the faceplate, chamber, or substrate support of greater than, for example, 2,500 W, oxidation may be too strong, and other materials in the structure 300 may be oxidized. Additionally, at greater plasma powers, damage may occur to the structure to the structure 300. However, to ensure sufficient oxidation of the silicon-containing material 315, the plasma power source may deliver a plasma power to the faceplate, chamber, or substrate support of greater than or about 500 W, and may deliver a power of greater than or about 600 W, greater than or about 700 W, greater than or about 800 W, greater than or about 900 W, greater than or about 1,000 W, or more.

During the conversion operation, a bias power source may be engaged, such as to the substrate support, to provide a bias to the plasma generated above the substrate. This may draw plasma effluents to the substrate, which may bombard the film and cause conversion of the deposited silicon-containing material 315 to silicon-and-oxygen-containing material. Applying greater bias may increase a directionality of delivery perpendicular to a plane across the substrate. Accordingly, by reducing the bias power supplied, the amount of directionality may reduce, which may increase interaction of the plasma effluents within the feature. Conversely, plasma effluents delivered more directionally may penetrate the remaining silicon-containing material 315 formed at the bottom of the features 310 and/or on the substrate 305. During operation 230, the oxygen radicals and ions may readily penetrate the materials formed within the features 310, and may convert the silicon-containing material 315 to silicon-and-oxygen-containing material 320. The bias power applied may be relatively low to limit sputtering of the produced film as well as to limit any potential damage to the structure. For example, the bias plasma power may be maintained at less than or about 1000 W to not damage the underlying structure, and may be maintained at less than or about 900 W, less than or about 800 W, less than or about 700 W, less than or about 600 W, less than or about 500 W, less than or about 400 W, less than or about 300 W, less than or about 200 W, less than or about 100 W, less than or about 90 W, less than or about 80 W, less than or about 70 W, less than or about 60 W, less than or about 50 W, or less. While in some conversion operations a source power may be higher than a bias power, the source power may alternatively be maintained below the bias power in other conversion operations.

Subsequent oxidation, in some embodiments of the present technology, an etch operation may be performed to etch back a portion of the formed material. This operation may be performed in the same chamber as the deposition and/or conversion, and may be performed in a cyclic process to fill the feature. In some embodiments, the oxygen-containing precursor flow may be halted and the processing region may be purged. Subsequent a purge, an etch precursor, such as a halogen-containing precursor, may be provided to the processing region of the semiconductor processing chamber at operation 235. In embodiments, the etchant precursor may be a fluorine-containing precursor. Etch plasma effluents may be formed at operation 240, which may also be an inductively-coupled plasma formed within the processing region, although in some embodiments a capacitively-coupled plasma may similarly be applied. The etch plasma effluents may be formed by applying a plasma power to the faceplate, chamber, or substrate support, and in some embodiments no other power source may be engaged.

Any fluorine-containing precursor may be utilized to generate a plasma within the processing region by delivering power to the faceplate from the plasma power source. In some embodiments diatomic fluorine (F₂), nitrogen trifluoride (NF₃) with or without H₂, ammonia (NH₃), octafluorocyclobutane (C₄F₈), carbon tetrafluoride (CF₄), hexafluorobutadiene (C₄F₆), or other fluorocarbons may be used as the fluorine-containing precursor to produce the etch plasma, along with one or more additional precursors.

The source plasma power in some embodiments may be less than the plasma power used during the deposition, but may be greater than the plasma power used during the conversion. For example, the plasma power delivered may be greater than or about 1,000 W, and may be greater than or about 1,500 W, greater than or about 1,750 W, greater than or about 2,000 W, greater than or about 2,250 W, greater than or about 2,500 W, greater than or about 2,750 W, greater than or about 3,000 W, greater than or about 3,250 W, greater than or about 3,500 W, greater than or about 3,750 W, greater than or about 4,000 W, or more. By increasing the source plasma power during the etch plasma formation, dissociation of the fluorine-containing precursor may be increased, which may increase the flux of the plasma effluents and increase etching of material. While this may increase a removal rate of the converted silicon-containing material, a flow rate may be adjusted to limit the amount of radical species present. This may prevent removing too much of the material that gap filling would be slowed and may prevent damage to other materials in the structure 300.

Similar to the conversion operations, during the etch operation, the bias power source may be engaged to provide a bias to the plasma generated above the substrate. This may draw plasma effluents to the substrate, which may bombard the film and increase etching of the converted silicon-containing material. By adjusting the source power and the bias power applied, an etching operation may be performed, which may reduce sidewall coverage of the deposited material. Aspects of the bias power may also be adjusted, which may also limit damage to the underlying structure. For example, the bias power may be maintained below or about 1,750 W, and may be below or about 1,700 W, below or about 1,600 W, below or about 1,500 W, below or about 1,400 W, below or about 1,300 W, or less. While in some operations a bias power may be higher than a plasma source power, the bias power may alternatively be maintained below the plasma power in other operations.

Again, applying greater bias may increase a directionality of delivery perpendicular to a plane across the substrate. Accordingly, by increasing the bias power supplied, the amount of directionality may increase, which may remove material overhanging and blocking access to within the feature 310. The plasma effluents may then etch the converted silicon-containing material, such as the silicon-and-oxygen containing material, at operation 245, and may remove the silicon-and-oxygen-containing material from the sidewalls of the features 310. The plasma effluents may fully remove converted silicon-containing material from the sidewalls of the features 310 above a base fill of the converted silicon-containing material. The base fill of the converted silicon-containing material may refer to the silicon-containing material deposited at the bottom of the features 310, or on the previously deposited silicon-containing material toward the bottom of the features 310.

Additional adjustments may be made to further increase deposition of material, conversion of deposited material, or etching of deposited material by adjusting one or more characteristics of the plasma power or bias power being supplied. For example, in some embodiments both the plasma power source and bias power source may be operated in a continuous wave mode. Additionally, one or both of the power sources may be operated in a pulsed mode. In some embodiments, the source power may be operated in a continuous wave mode or pulsed mode while the bias power is operated in a pulsed mode. A radio frequency (RF) frequency for the source power and/or bias power may be greater than or about 1 MHz, and may be greater than or about 3 MHz, greater than or about 5 MHz, greater than or about 13.5 MHz, greater than or about 15 MHz, greater than or about 17.5 MHz, greater than or about 20 MHz, greater than or about 22.5 MHz, greater than or about 25 MHz, greater than or about 27 MHz, greater than or about 27.5 MHz, greater than or about 30 MHz, greater than or about 35 MHz, greater than or about 40 MHz, greater than or about 45 MHz, greater than or about 50 MHz, greater than or about 55 MHz, greater than or about 60 MHz, or more. At higher frequencies for the source power, sputtering of the deposited material may be minimized during conversion. In embodiments, the RF frequency for the source power and/or the bias power may be less than or about 5 MHz, and may be less than or about 4 MHz, less than or about 3 MHz, less than or about 2 MHz, less than or about 1 MHz, less than or about 750 kHz, less than or about 500 kHz, less than or about 400 kHz, less than or about 350 kHz, or less. The source power and the bias power may both be capable of operating in a continuous wave mode or in a pulsing mode where both powers are operated in the same mode or in different modes. In embodiments, the duty cycle of the bias power may be less than or about 75%, and the bias power may be operated at a duty cycle of less than or about 70%, less than or about 60%, less than or about 50%, less than or about 40%, less than or about 30%, less than or about 20%, less than or about 10%, less than or about 5%, or less. By operating the bias power for a reduced duty cycle, such as an on-time duty of less than or about 50%, a greater amount of time per cycle may be performing a more isotropic etch within the feature, which may better remove material from the sidewalls. Additionally operating the bias power at a reduced duty cycle may result in less sputtering of material deposited at upper portions of the features, such as the overhang. In embodiments, a pulsing frequency for source or bias power maybe be less than or about 70 kHz, and may be less than or about 60 kHz, less than or about 50 kHz, less than or about 40 kHz, less than or about 30 kHz, or less.

As shown in FIG. 2, the deposition, conversion, and etch operations may be repeated any number of times in cycles to fill features in embodiments of the present technology. As shown in FIG. 3C, the deposition, conversion, and etch operations may fill features with silicon-containing material, such as amorphous silicon that may be converted to silicon-and-oxygen-containing material 320. For example, the processes may be repeated for a second cycle, a third cycle, a fourth cycle, a fifth cycle, a sixth cycle, a seventh cycle, or any number of cycles necessary to completely fill the features 310 with silicon-and-oxygen-containing material 320.

Temperature and pressure may also impact operations of the present technology. For example, the process may be performed at a temperature less than or about 550° C., and may be performed at a temperature less than or about less than or about 525° C., less than or about 500° C., less than or about 475° C., less than or about 450° C., less than or about 425° C., less than or about 400° C., less than or about 375° C., less than or about 350° C., less than or about 325° C., less than or about 300° C., or lower. Additionally, the process may be performed at a temperature greater than or about 275° C., and may be performed at a temperature greater than or about 300° C., greater than or about 325° C., greater than or about 350° C., greater than or about 375° C., greater than or about 400° C., greater than or about 425° C., greater than or about 450° C., greater than or about 475° C., greater than or about 500° C., greater than or about 525° C., or more. The temperature may be maintained in any of these ranges throughout the method, including during the treatment and etching. At higher temperatures, crystallized silicon-containing material may be formed instead of an amorphous silicon-containing material. Additionally, higher temperature may be above a thermal budget depending on the structure.

Pressure within the semiconductor processing chamber may be kept relatively low for any of the processes as well, such as at a chamber pressure of less than or about 500 mTorr, and pressure may be maintained at less than or about 250 mTorr, less than or about 100 mTorr, less than or about 50 mTorr, less than or about 40 mTorr, less than or about 30 mTorr, less than or about 25 mTorr, less than or about 20 mTorr, less than or about 15 mTorr, less than or about 10 mTorr, less than or about 9 mTorr, less than or about 8 mTorr, less than or about 7 mTorr, less than or about 6 mTorr, less than or about 5 mTorr, less than or about 4 mTorr, less than or about 3 mTorr, less than or about 2 mTorr, less than or about 1 mTorr, or less. However, lower pressures may result in a slower fill rate of the features during the deposition, which may control fill of the features 310 and prevent clogging or pinch off. Additionally, higher pressures may result in reduced pattern loading and/or line bending. Further, reduced pressures during the conversion operation may result in improved oxidation due to increased ionization and energy of the conversion plasma effluents. Finally, lower pressures during the etch operation to etch material may reduce dissociation and the resultant etch rate, which may prevent etching of materials other than the silicon-and-oxygen-containing material. By performing processes according to some embodiments of the present technology, improved fill of narrow features utilizing silicon-containing materials, such as silicon-and-oxygen-containing material, may be produced.

In the preceding description, for the purposes of explanation, numerous details have been set forth in order to provide an understanding of various embodiments of the present technology. It will be apparent to one skilled in the art, however, that certain embodiments may be practiced without some of these details, or with additional details.

Having disclosed several embodiments, it will be recognized by those of skill in the art that various modifications, alternative constructions, and equivalents may be used without departing from the spirit of the embodiments. Additionally, a number of well-known processes and elements have not been described in order to avoid unnecessarily obscuring the present technology. Accordingly, the above description should not be taken as limiting the scope of the technology. Additionally, methods or processes may be described as sequential or in steps, but it is to be understood that the operations may be performed concurrently, or in different orders than listed.

Where a range of values is provided, it is understood that each intervening value, to the smallest fraction of the unit of the lower limit, unless the context clearly dictates otherwise, between the upper and lower limits of that range is also specifically disclosed. Any narrower range between any stated values or unstated intervening values in a stated range and any other stated or intervening value in that stated range is encompassed. The upper and lower limits of those smaller ranges may independently be included or excluded in the range, and each range where either, neither, or both limits are included in the smaller ranges is also encompassed within the technology, subject to any specifically excluded limit in the stated range. Where the stated range includes one or both of the limits, ranges excluding either or both of those included limits are also included.

As used herein and in the appended claims, the singular forms “a”, “an”, and “the” include plural references unless the context clearly dictates otherwise. Thus, for example, reference to “a silicon-containing precursor” includes a plurality of such precursors, and reference to “the silicon-containing material” includes reference to one or more materials and equivalents thereof known to those skilled in the art, and so forth.

Also, the words “comprise(s)”, “comprising”, “contain(s)”, “containing”, “include(s)”, and “including”, when used in this specification and in the following claims, are intended to specify the presence of stated features, integers, components, or operations, but they do not preclude the presence or addition of one or more other features, integers, components, operations, acts, or groups.

1. A semiconductor processing method comprising:
providing a silicon-containing precursor to a processing region of a semiconductor processing chamber, wherein a substrate is housed in the processing region, wherein the substrate defines a feature, and wherein the processing region is at least partially defined between a faceplate and a substrate support on which the substrate is seated;
forming plasma effluents of the silicon-containing precursor;
depositing a silicon-containing material on the substrate;
providing an oxygen-containing precursor to the processing region of the semiconductor processing chamber;
forming plasma effluents of the oxygen-containing precursor;
contacting the silicon-containing material with the plasma effluents of the oxygen-containing precursor to oxidize the silicon-containing material, wherein the contacting forms a silicon-and-oxygen-containing material;
providing a fluorine-containing precursor to the processing region of the semiconductor processing chamber;
forming plasma effluents of the fluorine-containing precursor; and
contacting the silicon-and-oxygen-containing material with plasma effluents of the fluorine-containing precursor, wherein the contacting etches the silicon-and-oxygen-containing material from a top, a sidewall, or both of the feature.

2. The semiconductor processing method of claim 1, wherein:
the feature is characterized by an aspect ratio of greater than or about 1:1; and
the feature is characterized by a width across the feature of less than or about 100 nm.

3. The semiconductor processing method of claim 1, wherein the oxygen-containing precursor comprises diatomic oxygen (O₂), nitrous oxide (N₂O), or hydrogen peroxide (H₂O₂).

4. The semiconductor processing method of claim 1, further comprising:
applying a bias power from a bias power source to the substrate support.

5. The semiconductor processing method of claim 4, wherein a plasma power source is operated in a continuous wave mode while the bias power source is operated in a pulsing mode during the depositing and the etching.

6. The semiconductor processing method of claim 1, wherein:
the plasma effluents of the silicon-containing precursor are formed at a first power level from a plasma power source; and
the plasma effluents of the fluorine-containing precursor are formed at a second power level from the plasma power source greater than the first power level.

7. The semiconductor processing method of claim 1, wherein the fluorine-containing precursor comprises diatomic fluorine (F₂), nitrogen trifluoride (NF₃), ammonia (NH₃), octafluorocyclobutane (C₄F₈), carbon tetrafluoride (CF₄), or hexafluorobutadiene (C₄F₆).

8. The semiconductor processing method of claim 1, wherein the etching removes silicon-and-oxygen-containing material at a rate of less than or about 10 Å/second.

9. The semiconductor processing method of claim 1, wherein the method is repeated for a second cycle.

10. The semiconductor processing method of claim 1, wherein a temperature of the substrate is maintained at a temperature of less than or about 450° C.

11. The semiconductor processing method of claim 1, wherein a pressure within the semiconductor processing chamber is maintained at a pressure of less than or about 10 Torr.

12. A semiconductor processing method comprising:
i) forming plasma effluents of a silicon-containing precursor;
ii) depositing a silicon-containing material on a substrate, wherein the substrate defines a feature, wherein the substrate is seated on a substrate support;
iii) forming plasma effluents of an oxygen-containing precursor;
iv) contacting the silicon-containing material with the plasma effluents of the oxygen-containing precursor to form a silicon-and-oxygen-containing material;
v) forming plasma effluents of a fluorine-containing precursor;
vi) contacting the silicon-and-oxygen-containing material with plasma effluents of the fluorine-containing precursor, wherein the contacting etches the silicon-and-oxygen-containing material from a sidewall of the feature; and
repeating operations i) through vi) to iteratively fill the feature.

13. The semiconductor processing method of claim 12, wherein a plasma power during operation iii) is maintained at greater than or about 600 W.

14. The semiconductor processing method of claim 12, wherein a plasma power is pulsed during operations i) through iv).

15. The semiconductor processing method of claim 12, wherein the etching fully removes the silicon-and-oxygen-containing material from sidewalls of the feature above a base fill of the feature.

16. The semiconductor processing method of claim 12, further comprising:
applying a bias power from a bias power source during the semiconductor processing method.

17. The semiconductor processing method of claim 16, wherein the bias power source is operated at a plasma power of less than or about 750 W.

18. The semiconductor processing method of claim 12, wherein a temperature of the substrate is maintained at a temperature of less than or about 450° C.

19. A semiconductor processing method comprising:
providing a silicon-containing precursor to a processing region of a semiconductor processing chamber, wherein a substrate is housed in the processing region, wherein the substrate defines a feature, and wherein the processing region is at least partially defined between a faceplate and a substrate support on which the substrate is seated;
forming plasma effluents of the silicon-containing precursor, wherein the plasma effluents of the silicon-containing precursor are formed at a first power level from a plasma power source;
depositing a silicon-containing material on the substrate;
providing an oxygen-containing precursor to the processing region of the semiconductor processing chamber;
forming plasma effluents of the oxygen-containing precursor;
contacting the silicon-containing material with the plasma effluents of the oxygen-containing precursor to oxidize the silicon-containing material, wherein the contacting forms a silicon-and-oxygen-containing material;
providing a fluorine-containing precursor to the processing region of the semiconductor processing chamber;
forming plasma effluents of the fluorine-containing precursor, wherein the plasma effluents of the fluorine-containing precursor are formed at a second power level from the plasma power source greater than the first power level; and
contacting the silicon-and-oxygen-containing material with plasma effluents of the fluorine-containing precursor, wherein the contacting etches the silicon-and-oxygen-containing material from sidewalls of the feature above a base fill of the feature.

20. The semiconductor processing method of claim 19, wherein a temperature of the substrate is maintained at a temperature of less than or about 450° C.
